(19) United States
(12) Patent Application Publication
(10) Pub. No.: US 2015/0243218 A1
(43) Pub. Date: Aug. 27, 2015

(54) OLED DISPLAY

(71) Applicant: InnoLux Corporation, Miao-Li County (TW)

(72) Inventors: Ming-Chun TSENG, Miao-Li County (TW); Cheng-Hsu CHOU, Miao-Li County (TW); Chun-Yu CHEN, Miao-Li County (TW); Kung-Chen KUO, Miao-Li County (TW)

(21) Appl. No.: 14/615,919

(22) Filed: Feb. 6, 2015

(30) Foreign Application Priority Data
Feb. 21, 2014 (TW) 103105784

(51) Int. Cl. G09G 3/32; H01L 27/32

(52) U.S. Cl. CPC G09G 3/3258; H01L 27/3248; G09G 3/3233; G09G 2300/0819; G09G 2320/0233; G09G 2320/0219

(57) ABSTRACT

An organic light-emitting diode (OLED) display is provided. A pixel array includes a plurality of pixels, wherein the pixel includes an emitting device and a driving transistor. A first gate of the driving transistor receives a driving signal, and a second gate of the driving transistor receives a compensation signal. A gate driving circuit provides the compensation signal according to a total current value flowing through the emitting devices of the pixels. When the total current value is between a first reference value and a second reference value, the gate driving circuit adjusts a voltage level of the compensation signal according to the total current value. The first reference value is 90% of a target current value, and the second reference value is 50% of a target current value.

### CROSS REFERENCE TO RELATED APPLICATIONS

This application claims priority of Taiwan Patent Application No. 103105784, filed on Feb. 21, 2014, the entirety of which is incorporated by reference herein.

### BACKGROUND OF THE INVENTION

1. Field of the Invention

The invention relates to an organic light-emitting diode (OLED) display, and more particularly to an OLED display capable of automatically compensating threshold voltages of transistors.

2. Description of the Related Art

Generally, an organic light-emitting diode (OLED) is a self-emissive display element that emits light by electrically exciting a luminous organic compound. The OLED has recently received attention and application in the field of flat panel displays, television screens, computer displays, and portable electronic device screens. The OLED, when used in a display, offers several advantages over flat-panel displays, such as its self-emissive ability which retires the backlight of the LED, wider viewing angles, and improved brightness.

Due to the use of Thin Film Transistor-Active Matrix Organic Light Emitting Diodes (TFT-AMOLEDs), the display has a low manufacturing cost, high response speed (more than a hundred times that of traditional LCD displays), low power consumption, a huge operating temperature range, as well as a light weight, etc., and therefore, use of TFT-AMOLEDs has become mainstream.

There are two ways of manufacturing the TFT-AMOLED display; one is by using Low Temperature Poly-silicon (LTPS) TFT technology and another one is by using Amorphous Silicon (a-Si) TFT technology. When driving the TFT, the LTPS technology usually adopts P type transistors as the driving TFT, and the a-Si usually adopts N type transistors as the driving TFT.

The a-Si technology results in a comparably better thin-film transistor uniformity, as well as lower production costs. However, the disadvantage of using the N type driving TFT is that the threshold voltages of transistors may drift after being used for a period of time. Therefore, even after applying the same driving voltage, after being used for a period of time, the driving TFT is unable to output the same driving current as initially, causing some lines to undesirably become darker or brighter than they should be. This is called the MURA effect.

Therefore, an OLED display is desired that is capable of automatically compensating for threshold voltage offset of the transistors according to actual applications

### BRIEF SUMMARY OF THE INVENTION

Organic light-emitting diode (OLED) displays are provided. An embodiment of an OLED display is provided. The OLED display comprises a pixel array comprising a plurality of pixels, and a gate driving circuit. The pixel comprises an emitting device and a driving transistor coupled to the emitting device. The driving transistor has a first gate for receiving a driving signal and a second gate for receiving a compensation signal. The gate driving circuit provides the compensation signal according to a total current value flowing through the emitting devices of the plurality of pixels. When the total current value is between a first reference value and a second reference value, the gate driving circuit adjusts a voltage level of the compensation signal according to the total current value. The first reference value is 90% of a target current value, and the second reference value is 50% of the target current value.

Furthermore, another embodiment of an OLED display is provided. The OLED display comprises a pixel array comprising a plurality of pixels and a gate driving circuit. The plurality of pixels are divided into a plurality of pixel groups. The pixel comprises an emitting device and a driving transistor coupled to the emitting device. The driving transistor has a first gate for receiving a driving signal and a second gate for receiving a compensation signal. The gate driving circuit provides the compensation signal to the corresponding driving transistors of the pixel groups according to a total current value flowing through the emitting devices of the pixel groups, respectively. When the total current value of the pixel group is between a first reference value and a second reference value, the gate driving circuit adjusts a voltage level of the compensation signal according to the total current value. The first reference value is 90% of a target current value, and the second reference value is 50% of the target current value.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a pixel of an Active Matrix Organic Light Emitting Diode (AMPLED) display according to an embodiment of the invention;

FIG. 2 shows a structure schematic illustrating a dual-gate driving transistor according to an embodiment of the invention;

FIG. 3 shows an AMPLED display according to an embodiment of the invention;

FIG. 4 shows an adjustment method for adjusting a back gate of driving transistors of an organic light emitting diode (OLED) display according to an embodiment of the invention; and

FIG. 5 shows an AMPLED display 500 according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

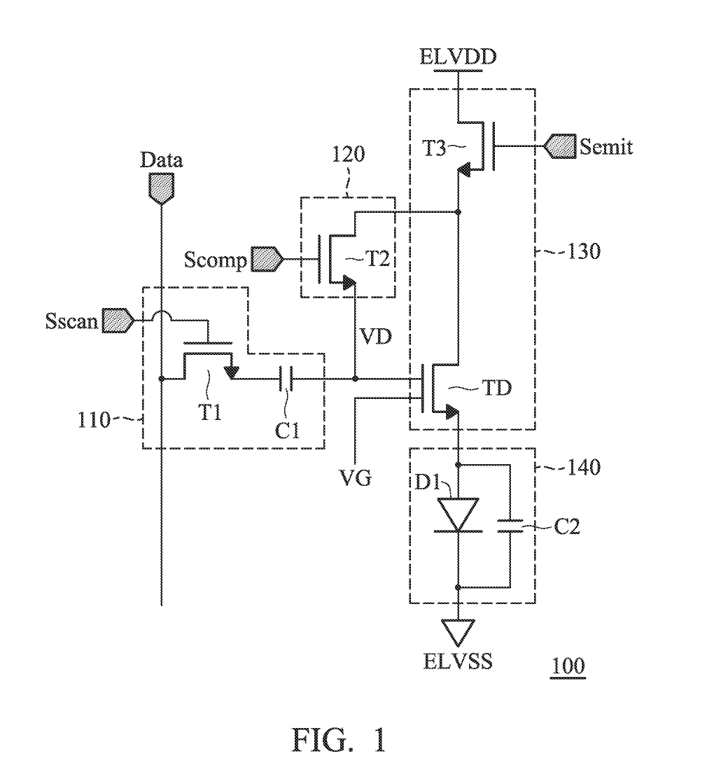

FIG. 1 shows a pixel 100 of an Active Matrix Organic Light Emitting Diode (AMPLED) display according to an embodiment of the invention. The pixel 100 comprises a data sampling unit 110, a compensation unit 120, a driving unit 130 and an emitting unit 140. The data sampling unit 110 comprises a transistor T1 and a capacitor C1. The transistor T1 is controlled by a scan signal Sscan, to sample a gray data Data and store the sampled gray data Data to the capacitor C1, so as to provide a driving signal VD. The driving unit 130 comprises a transistor T3 and a driving transistor TD, wherein the transistor T3 coupled between a power ELVDD and the driving transistor TD is controlled by an enable signal Semit. In the embodiment, the driving transistor TD is a dual-gate thin film transistor (TFT), wherein the dual gates of the driving transistor TD are controlled by the driving signal VD and a compensation signal VG, respectively. Furthermore, the compensation unit 120 comprises a transistor T2, wherein the transistor T2 is used to adjust the driving signal VD according to a compensation signal Scomp, so as to compensate an offset of a threshold voltage Vt of the driving transistor TD. The emitting unit 140 comprises an emitting diode D1 and a capacitor C2. The emitting diode D1 is coupled between the driving transistor TD and a ground ELVSS, and the capacitor C2 is coupled to the emitting diode D1 in parallel.

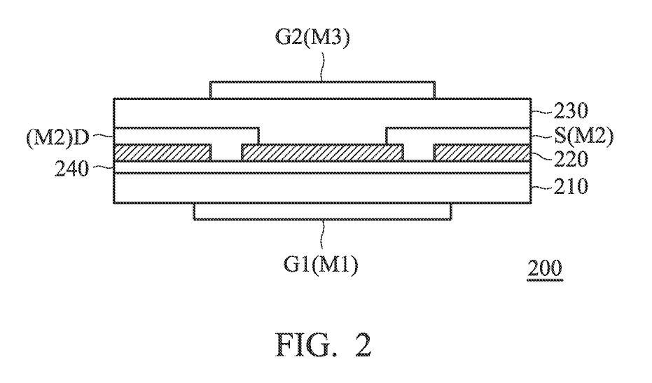

FIG. 2 shows a structure schematic illustrating a dual-gate driving transistor 200 according to an embodiment of the invention. A bottom gate G1 of the driving transistor 200 is formed by a first metal layer M1. A gate insulator (GI) 210 is formed on the bottom gate G1. A semiconductor layer 240 (e.g. IGZO or a-Si) is formed on the gate insulator 210. An etching stop layer (ELS) 220 is formed on the semiconductor layer 240. A drain D and a source S of the driving transistor 200 are formed by a second metal layer M2, and the drain D and the source S of the driving transistor 200 are disposed on the etching stop layer 220 and contact with the semiconductor layer 240. A passivation (PV) layer 230 is formed on the second metal layer M2. A back gate G2 is formed by a third metal layer M3 or ITO, and the back gate G2 is disposed on the passivation layer 230. In FIG. 2, the source S and the drain D of the driving transistor 200 are formed between the bottom gate G1 and the back gate G2. For the driving transistor 200, by adjusting a voltage of the back gate G2, a threshold voltage Vt can be adjusted, to solve shifts of gamma and optical properties (e.g., color mixing of International Commission on Illumination (CIE)). For example, when a voltage of the back gate G2 is increased, the threshold voltage Vt is decreased. Conversely, when the voltage of the back gate G2 is decreased, the threshold voltage Vt is increased.

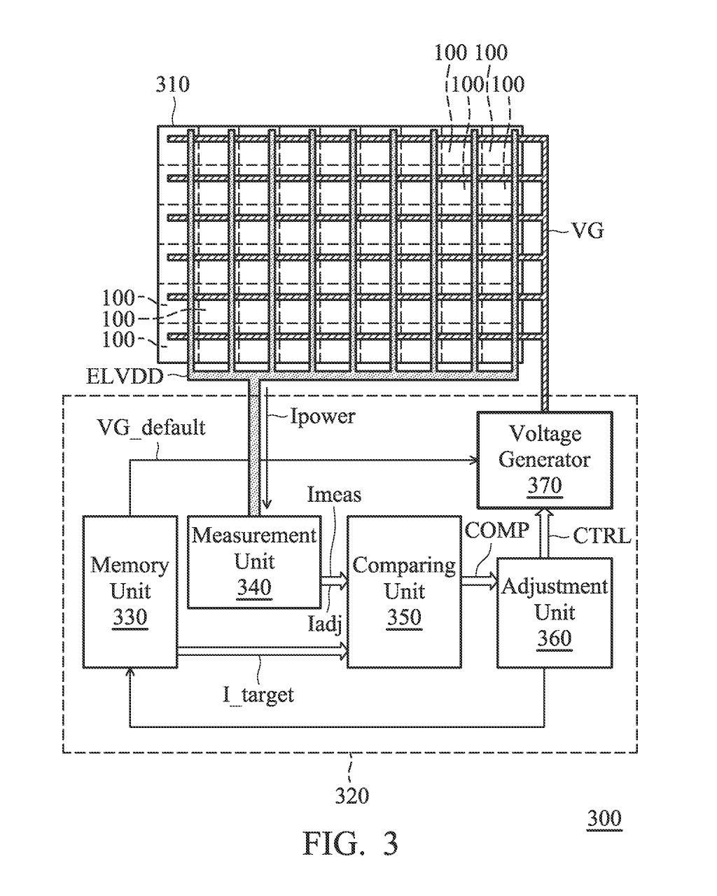

FIG. 3 shows an AMPLED display 300 according to an embodiment of the invention. The display 300 comprises a pixel array 310 and a back gate driving circuit 320. The pixel array 310 is formed by a plurality of the pixels 100. Referring to FIG. 1 and FIG. 3 together, according to a current Ipower of a power ELVDD in the current pixel array 310, i.e. a total current flowing through the emitting diodes D1 of the whole pixels 100, the back gate driving circuit 320 can dynamically adjust a voltage level of the compensation signal VG, so as to compensate for the threshold voltage Vt in the pixel array 310. The back gate driving circuit 320 comprises a memory unit 330, a measurement unit 340, a comparing unit 350, an adjustment unit 360 and a voltage generator 370. The memory unit 330 is used to store a target current value I_target of the pixel array 310 and a current voltage level VG_default of the compensation signal VG, wherein the target current value I_target is determined according to actual applications. The measurement unit 340 is coupled to the power ELVDD of the pixel array 310, wherein the measurement unit 340 measures the current Ipower flowing through the power ELVDD, to obtain a total current value Imeas. For example, the target current value I_target represents an initial measurement value of a specific gray level (e.g. 64), and the total current value Imeas represents a current measurement value of the specific gray level. In another embodiment, the measurement unit 340 is coupled to a ground ELVSS of the pixel array 310, so as to measure the current Ipower flowing through the ground ELVSS, to obtain the total current value Imeas. Next, the comparing unit 350 obtains a deviation rate ΔI between the current value Imeas and the target current value I_target according to the total current value Imeas and the target current value I_target, wherein ΔI=(I_target−Imeas)/I_target. Next, the comparing unit 350 provides a comparing result COMP to the adjustment unit 360 according to the deviation rate ΔI. The adjustment unit 360 determines whether the deviation rate ΔI is between a adjustment range (between 10% and 50%) according to the comparing result COMP, e.g. 10%≦ΔI≦50%. In other words, according to the comparing result COMP, it is determined whether the total current value Imeas is between 50% and 90% of the target current value I_target. When the comparing result COMP indicates that the deviation rate ΔI is between the adjustment range, the adjustment unit 360 provides a control signal CTRL to the voltage generator 370 according to the deviation rate ΔI of the comparing result COMP, wherein the control signal CTRL comprises information regarding a adjustment value ΔV of the compensation signal VG. Next, the voltage generator 370 adjusts the voltage level of the compensation signal VG according to the control signal CTRL, i.e. VG=VG_default+ΔV, wherein VG_default is the current voltage level stored in the memory unit 330. In one embodiment, the voltage generator 370 is a DC to DC converter. Next, the measurement unit 340 re-measures the current Ipower to obtain an adjusted total current value Iadj. Next, the comparing unit 350 compares the adjusted total current value Iadj with the total current value Imeas. In one embodiment, the total current value Imeas is stored in the registers of the comparing unit 350. In another embodiment, the total current value Imeas is stored in the memory unit 330 by the measurement unit 340. If the adjusted total current value Iadj is equal to the total current value Imeas, it is determined that the current flowing through the emitting devices D1 of the whole pixels 100 cannot be changed by adjusting the voltage level of the compensation signal VG. Therefore, the comparing unit 350 will notice the adjustment unit 360, to provide the compensation signal VG with the current voltage level VG_default according to the current voltage level VG_default stored in the memory unit 330. Conversely, if the adjusted total current value Iadj is different from the total current value Imeas, it is determined that the adjusted voltage level of the compensation signal VG is capable of compensating for the threshold voltage Vt of the dual-gate driving transistors. Therefore, the comparing unit 350 will notify the adjustment unit 360, so as to update the current voltage level VG_default of the memory unit 330 according to the adjusted voltage level of the compensation signal VG, i.e. VG_default=VG.

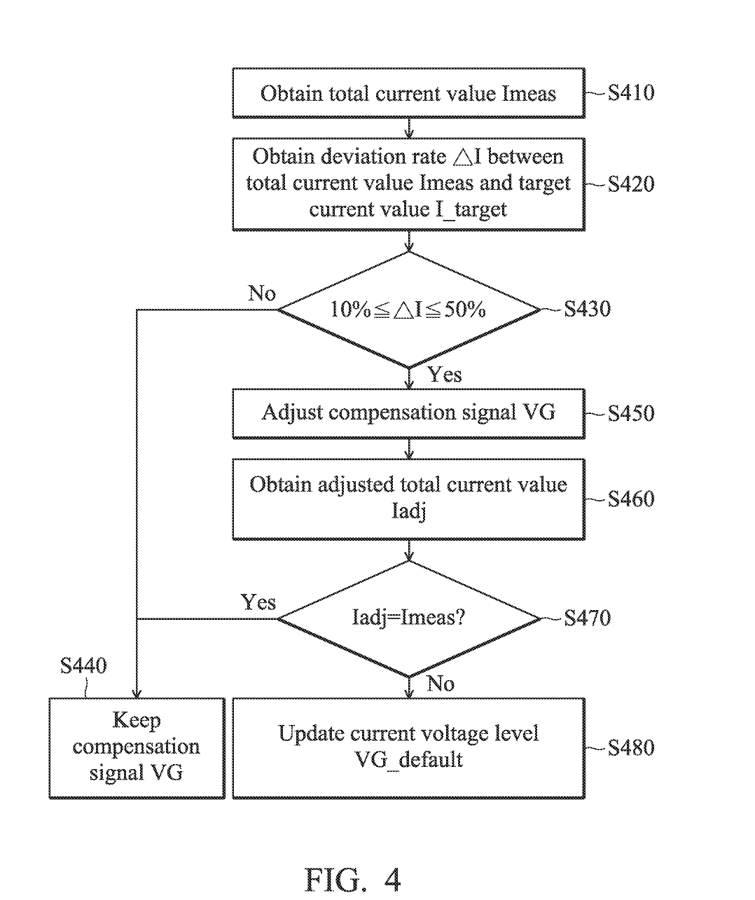

FIG. 4 shows an adjustment method for adjusting a back gate of driving transistors of an organic light emitting diode (OLED) display according to an embodiment of the invention. Referring to FIG. 3 and FIG. 4 together, first, in step S410, the measurement unit 340 measures the current Ipower of the power ELVDD or the ground ELVSS, to obtain the total current value Imeas. Next, in step S420, by comparing the total current value Imeas and the target current value I_target stored in the memory unit 330, the comparing unit 350 obtains the deviation rate ΔI between the total current value Imeas and the target current value I_target, and provides the comparing result COMP to the adjustment unit 360. Next, in step S430, the adjustment unit 360 determines whether the deviation rate ΔI is between 10% and 50% according to the comparing result COMP. If the deviation rate ΔI is larger than 50% or smaller than 10%, the adjustment unit 360 provides the control signal CTRL to the voltage generator 370, so as to keep the voltage level of the compensation signal VG. Thus, the voltage generator 370 continues to provide the compensation signal VG according to the current voltage level VG_default stored in the memory unit 330 (step S440). Conversely, if the deviation rate ΔI is between 10% and 50%, the adjustment unit 360 provides the control signal CTRL to the voltage generator 370, so as to adjust the voltage level of the compensation signal VG according to the deviation rate ΔI. In one embodiment, the adjustment unit 360 obtains the adjustment value ΔV corresponding to the deviation rate ΔI according to a lookup table. Thus, the voltage generator 370 changes the voltage level of the compensation signal VG according to the current voltage level VG_default and the adjustment value ΔV, i.e. VG=VG_default+ΔV (step S450). Next, in response to the changed compensation signal VG, the measurement unit 340 re-measures the current Ipower, to obtain the adjusted total current value Iadj (step S460). Next, in step S470, the comparing unit 350 determines whether the adjusted total current value Iadj is equal to the total current value Imeas. If the total current value Iadj is equal to the total current value Imeas, it is determined that current flowing through the emitting devices D1 of the whole pixels 100 cannot be changed by adjusting the voltage level of the compensation signal VG. Thus, the adjustment unit 360 provides the control signal CTRL to the voltage generator 370, so as to keep the voltage level of the compensation signal VG (step S440). Conversely, if the total current value Iadj is different from the total current value Imeas, it is determined that the current flowing through the emitting devices D1 of the whole pixels 100 can be controlled effectively by adjusting the voltage level of the compensation signal VG. Thus, the adjustment unit 360 updates the current voltage level VG_default of the memory unit 330 according to the changed voltage level of the compensation signal VG (step S480), i.e. VG_default=VG.

The following Table 1 shows a schematic illustrating how the compensation signal VG is adjusted according to the current Ipower. It should be noted that the values in Table 1 are used as an example and are not to limit the invention.

TABLE 1

| | Initial | | First | | Second | | Third | |
|---|---|---|---|---|---|---|---|---|
| | setting | | Adjustment | | Adjustment | | Adjustment | |
| Imeas | 24 | mA | 21.6 | mA | 21.6 | mA | 21.6 | mA |
| VG_default | −1 | V | −1 | V | 1.2 | V | 1.67 | V |
| VG | | | 1.2 | V | 1.67 | V | 2.05 | |
| Iadj | | | 24 | mA | 24 | mA | 24 | mA |

Referring to FIG. 3 and Table 1 together, first, the back gate driving circuit 320 provides −1V of the compensation signal VG to the pixel array 310 according to predetermined current voltage level VG_default, and stores the measured initial total current value Imeas into the memory unit 330 as the target current value I_target, i.e. I_target=24 mA. Next, when the back gate driving circuit 320 performs a first adjustment, the measurement unit 340 obtains that the total current value Imeas is 21.6 mA. Next, the comparing unit 350 obtains that the deviation rate ΔI is 10%, e.g. (24−21.6)/24=10%. Thus, the back gate driving circuit 320 provides 1.2V of the compensation signal VG to the pixel array 310 according to the deviation rate ΔI. Next, the measurement unit 340 obtains that the total current value Iadj is 24 mA. Due to the adjusted total current value Iadj being different from the total current value Imeas, the adjustment unit 360 updates the current voltage level VG_default to 1.2V for a second adjustment. Similarly, when the second adjustment is performed, if the total current value Iadj (e.g. 24 mA) is different from the total current value Imeas (e.g. 21.6 mA), the adjustment unit 360 updates the current voltage level VG_default to 1.67V for a subsequent adjustment, and so on. Therefore, when the current I_power is decreased, the back gate driving circuit 320 can dynamically adjust the compensation signal VG, so as to compensate the threshold voltage Vt of the driving transistors.

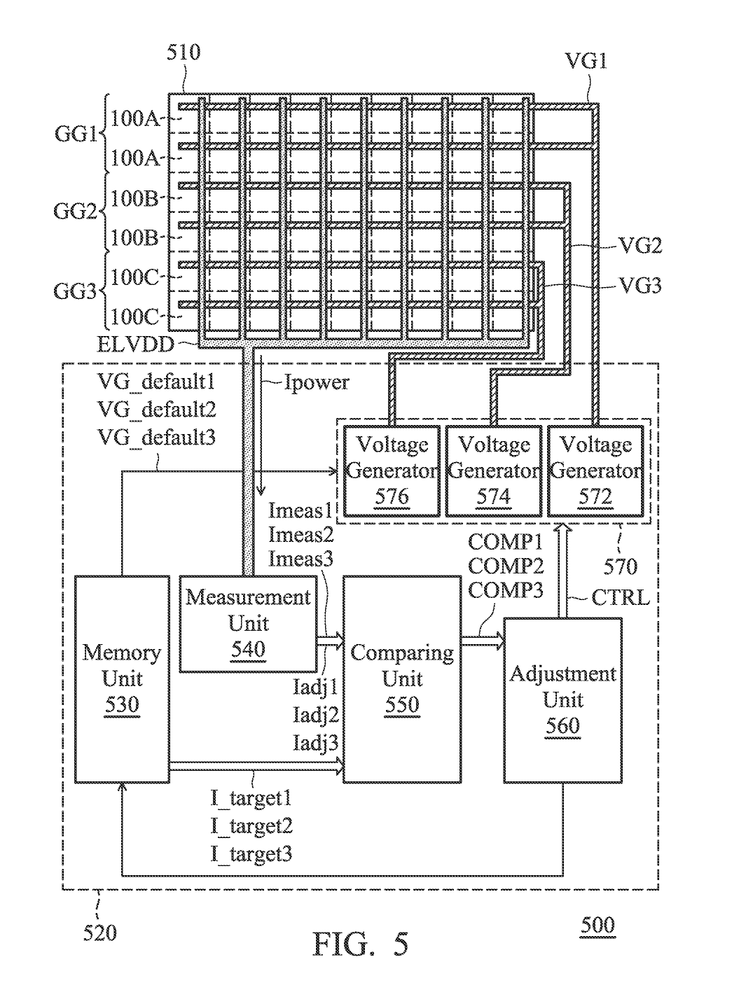

FIG. 5 shows an AMPLED display 500 according to another embodiment of the invention. The display 500 comprises a pixel array 510 and a back gate driving circuit 520. Compared with the pixel array 310 of FIG. 3, the pixel array 510 is formed by a plurality of pixel groups GG1, GG2 and GG3, wherein the pixel group GG1 comprises a plurality of pixels 100A, the pixel group GG2 comprises a plurality of pixels 100B, and the pixel group GG3 comprises a plurality of pixels 100C. Furthermore, the back gate driving circuit 520 comprises a memory unit 530, a measurement unit 540, a comparing unit 550, an adjustment unit 560 and a voltage generating module 570, wherein the voltage generating module 570 comprises a plurality of voltage generators 572, 574 and 576. The voltage generator 572 is used to provide a compensation signal VG1 to the dual-gate driving transistors of the pixels 100A in the pixel group GG1, the voltage generator 574 is used to provide a compensation signal VG2 to the dual-gate driving transistors of the pixels 100B in the pixel group GG2, and the voltage generator 576 is used to provide a compensation signal VG3 to the dual-gate driving transistors of the pixels 100C in the pixel group GG3. Thus, the different pixel groups can be compensated by the corresponding signals, respectively. For example, when the current of the emitting diodes D1 of the pixels 100A in the pixel group GG1 is measuring, the pixels 100B of the pixel group GG2 and the pixels 100C of the pixel group GG3 can be disabled by the enable signal Semit. Thus, the measurement unit 540 can obtain a total current value Imeas1 corresponding to the pixel group GG. Next, the comparing unit 550 generates a comparing result COMP1 according to the total current value Imeas1 and a target current value I_target1 corresponding to the pixel group GG1. Next, the adjustment unit 560 controls the voltage generator 572 according to the comparing result COMP1, to generate the compensation signal VG1. In FIG. 5, the target current values I_target1, I_target2 and I_target3 corresponding to the pixel groups GG1, GG2 and GG3 can be set to the same values or different values according to actual application, and the current voltage levels VG_default1, VG_default2 and VG_default3 corresponding to the pixel groups GG1, GG2 and GG3 also can be set to the same values or different values according to actual application. Therefore, the back gate driving circuit 520 can provide suitable compensation for the dual-gate driving transistors of different groups.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light-emitting diode (OLED) display, comprising:
a pixel array comprising a plurality of pixels, wherein the pixel comprises:
an emitting device; and
a driving transistor coupled to the emitting device, having a first gate for receiving a driving signal and a second gate for receiving a compensation signal; and
a gate driving circuit, providing the compensation signal according to a total current value flowing through the emitting devices of the plurality of pixels,
wherein when the total current value is between a first reference value and a second reference value, the gate driving circuit adjusts a voltage level of the compensation signal according to the total current value,
wherein the first reference value is 90% of a target current value, and the second reference value is 50% of the target current value.

2. The OLED display as claimed in claim 1, wherein when the total current value is larger than the first reference value or smaller than the second reference value, the gate driving circuit keeps the voltage level of the compensation signal.

3. The OLED display as claimed in claim 1, wherein the gate driving circuit comprises:
a memory unit, storing the target current value and a current voltage level value;
a measurement unit, obtaining the total current value;
a comparing unit, obtaining a comparing result according to the total current value and the target current value;
an adjustment unit, providing a control signal according to the comparing result; and
a voltage generator, generating the compensation signal according to the control signal.

4. The OLED display as claimed in claim 3, wherein the comparing result comprises a deviation rate between the total current value and the target current value, and when the comparing result indicates that the total current value is between the first and second reference values, the adjustment unit provides the control signal to the voltage generator according to the deviation rate, to change the voltage level of the compensation signal.

5. The OLED display as claimed in claim 4, wherein when the voltage level of the compensation signal is changed, the measurement unit obtains an adjusted total current value flowing through the emitting devices of the plurality of pixels, and when the adjusted total current value is different from the total current value, the adjustment unit updates the current voltage level value according to the changed voltage level of the compensation signal.

6. An organic light-emitting diode (OLED) display, comprising:
a pixel array comprising a plurality of pixels, wherein the plurality of pixels are divided into a plurality of pixel groups, wherein the pixel comprises:
an emitting device; and
a driving transistor coupled to the emitting device, having a first gate for receiving a driving signal and a second gate for receiving a compensation signal; and
a gate driving circuit, providing the compensation signal to the corresponding driving transistors of the pixel groups according to a total current value flowing through the emitting devices of the pixel groups, respectively,
wherein when the total current value of the pixel group is between a first reference value and a second reference value, the gate driving circuit adjusts a voltage level of the compensation signal according to the total current value,
wherein the first reference value is 90% of a target current value, and the second reference value is 50% of the target current value.

7. The OLED display as claimed in claim 6, wherein when the total current value of the pixel group is larger than the first reference value or smaller than the second reference value, the gate driving circuit keeps the voltage level of the compensation signal.

8. The OLED display as claimed in claim 7, wherein the gate driving circuit comprises:
a memory unit, storing the target current value of the pixel groups and a current voltage level value of the pixel groups;
a measurement unit, obtaining the total current value of the pixel groups;
a comparing unit, obtaining a comparing result of the pixel groups according to the total current value and the target current value of the pixel groups, respectively;
an adjustment unit, providing a control signal of the pixel groups according to the comparing result of the pixel groups; and
a plurality of voltage generators, wherein the voltage generator generates the compensation signal to the driving transistor of the corresponding pixel group according to the corresponding control signal.

9. The OLED display as claimed in claim 8, wherein the comparing result comprises a deviation rate between the total current value and the target current value of the pixel group, and when the comparing result indicates that the total current value of the pixel group is between the first and second reference values, the adjustment unit provides the control signal of the pixel group to the corresponding voltage generator according to the deviation rate, to change the voltage level of the compensation signal of the pixel group.

10. The OLED display as claimed in claim 9, wherein when the voltage level of the compensation signal of one of the pixel groups is changed, the measurement unit obtains an adjusted total current value flowing through the emitting devices of the plurality of pixels of the one of the pixel groups, and when the adjusted total current value is different from the total current value of the one of the pixel groups, the adjustment unit updates the current voltage level value of the one of the pixel groups according to the changed voltage level of the compensation signal of the one of the pixel groups.
